(19) United States
(12) Patent Application Publication
(10) Pub. No.: US 2026/0338847 A1
(43) Pub. Date: Oct. 29, 2026

(54) SYSTEM FOR ANALYZING ELECTROMAGNETIC INTERFERENCE EXCEEDANCE AND ANALYSIS METHOD THEREOF

(71) Applicant: Quanta Computer Inc., Taoyuan City (TW)

(72) Inventors: Wen-Cheng LIN, Taoyuan City (TW); Ping-Feng LEE, Taoyuan City (TW)

(21) Appl. No.: 19/293,216

(22) Filed: Aug. 7, 2025

(30) Foreign Application Priority Data
Apr. 28, 2025 (TW) 114115935

(51) Int. Cl. G01R 31/00; G06F 18/214

(52) U.S. Cl. CPC G01R 31/001; G06F 18/214; G06F 2218/12

(57) ABSTRACT

A method for performing electromagnetic interference (EMI) exceedance analysis is provided. The method includes obtaining a test spectrogram image of a target EMI. The method includes using a trained classification model to determine whether the test spectrogram image indicates a limit exceedance of the target EMI. In response to a determination that the test spectrogram image indicates the limit exceedance of the target EMI, the method includes using a trained object recognition model to detect one or more frequency exceedance points in the test spectrogram image and identifying a noise source corresponding to each of the frequency exceedance points.

### CROSS REFERENCE TO RELATED APPLICATIONS

This application claims priority of Taiwan patent application No. 114115935, filed Apr. 28, 2025, the entirety of which is incorporated by reference herein.

### TECHNICAL FIELD

The present disclosure relates to electromagnetic interference (EMI) exceedance analysis, and, in particular, it relates to a computer system and a method for EMI exceedance analysis.

### BACKGROUND

Electromagnetic Interference (EMI) refers to electromagnetic waves emitted by electronic devices or electrical systems that interfere with the normal operation of other devices, causing them to malfunction or to degrade their performance. This interference can come from a variety of sources, such as electronic devices, wireless communication devices, and even power lines.

EMI analysis and debugging often rely on professional engineers with many years of experience in EMI design and debugging. With their experience, these engineers are able to identify the source of interference and fine-tune it for specific frequencies. However, such a process often requires a lot of time and expertise, and such work can be more difficult and time-consuming for engineers who don't have a lot of experience.

Therefore, a system and method for the analysis of electromagnetic interference exceedance are needed to solve the problems mentioned above.

### BRIEF SUMMARY

One of the embodiments of the present invention provides a method for analyzing electromagnetic interference (EMI) exceedance implemented by a computer system. The method includes obtaining a test spectrogram image of a target EMI. The method includes using a trained classification model to determine whether the test spectrogram image indicates a limit exceedance of the target EMI. In response to a determination that the test spectrogram image indicates the limit exceedance of the target EMI, the method includes using a trained object recognition model to detect one or more frequency exceedance points in the test spectrogram image and to identify the noise source that corresponds to each of the frequency exceedance points.

In one of the embodiments, the computer system uses a first training dataset to train the trained classification model, wherein the first training dataset includes a plurality of first training data. Each first training data includes a training spectrogram image of a historical EMI and a first category label associated with the training spectrogram image. The first category label indicates whether the training spectrogram image shows an exceedance of the historical EMI.

In one of the embodiments, the computer system converts an EMI test report into a test report image and extracts the training spectrogram image from the test report image according to boundary information associated with the training spectrogram image.

In one of the embodiments, the computer system uses a second training dataset to train the trained object recognition model. The second training dataset includes a plurality of second training data. Each second training data includes an exceedance training spectrogram image of a historical EMI. Each second training data includes one or more positioning labels associated with the exceedance training spectrogram image. Each of the positioning labels corresponds to a frequency exceedance point of the historical EMI. Each second training data includes a second category label that is associated with each of the positioning labels. The second category label indicates the noise source category of the frequency exceedance point.

In one of the embodiments, the computer system converts an EMI test report into a test report image and parses the noise source category from the test report image.

One of the embodiments of the present invention provides a computer system for analyzing electromagnetic interference (EMI) exceedances. The computer system includes a storage device that is configured to store a program, and a processing device that is configured to load the program to perform the following steps. One step involves obtaining a test spectrogram image of a target EMI. One step involves using a trained classification model to determine whether the test spectrogram image indicates a limit exceedance of the target EMI. In response to a determination that the test spectrogram image indicates the limit exceedance of the target EMI, one step involves using a trained object recognition model to detect one or more frequency exceedance points in the test spectrogram image and to identify the noise source that corresponds to each of the frequency exceedance points.

In one of the embodiments, the processing device further uses a first training dataset to train the trained classification model. The first training dataset includes a plurality of first training data. Each first training data includes a training spectrogram image of a historical EMI and a first category label associated with the training spectrogram image. The first category label indicates whether the training spectrogram image shows an exceedance of the historical EMI.

In one of the embodiments, the processing device further converts the EMI test report into a test report image, and extracts the training spectrogram image from the test report image according to the boundary information associated with the training spectrogram image.

In one of the embodiments, the processing device further uses a second training dataset to train the trained object recognition model. The second training dataset includes a plurality of second training data. Each second training data includes an exceedance training spectrogram image of a historical EMI, one or more positioning labels, and a second category label. The positioning labels are associated with the exceedance training spectrogram image. Each of the positioning labels corresponds to a frequency exceedance point of the historical EMI. The second category label is associated with each of the positioning labels. The second category label indicates the noise source category of the frequency exceedance point.

In an embodiment, the processing device further converts the EMI test report into a test report image and parses the noise source category from the test report image.

### BRIEF DESCRIPTION OF THE DRAWINGS

The present disclosure can be more fully understood by reading the subsequent detailed description and examples with references made to the accompanying drawings. Furthermore, it should be understood that the execution order of the blocks in the flowcharts of this disclosure may be altered, and/or certain blocks may be modified, omitted, or combined.

FIG. 1 shows a block diagram of a computer system that depicts an electromagnetic interference exceedance analysis according to one of the embodiments of the present invention;

FIG. 2 shows a flow chart that shows an analytical method for analyzing electromagnetic interference exceedance according to one of the embodiments of the present invention;

FIG. 3 shows a schematic diagram of the structure of the first training dataset according to one of the embodiments of the present invention; and

FIG. 4 shows a schematic diagram of the structure of the second training dataset according to one of the embodiments of the present invention.

### DETAILED DESCRIPTION

The following description is made for the purpose of illustrating the general principles of the disclosure and should not be taken in a limiting sense. The scope of the disclosure is best determined by reference to the appended claims.

In the following embodiments, the same or similar elements or components will be represented by the same reference numerals.

In this specification and the claims, numerical designators such as “first,” “second,” and so on are used merely for convenience of description and do not imply any sequential order between them.

The following description of the embodiments of the apparatus or system also applies to the embodiments of the method and vice versa.

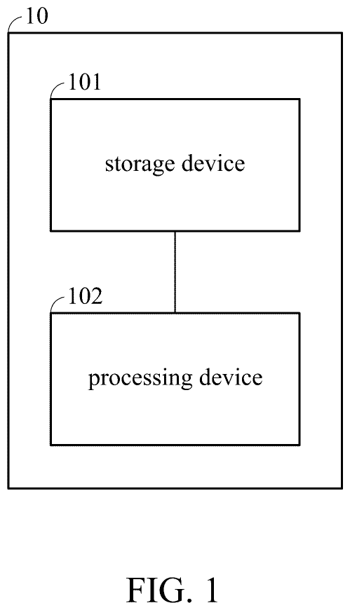

FIG. 1 is based on one of the embodiments of the present invention to illustrate an electromagnetic interference (EMI) system block diagram of computer system 10 for exceedance analysis. Computer system 10 can be a computer system that runs an operating system (e.g., Microsoft Windows, Mac OS, Linux, UNIX . . . etc.), such as personal computers (e.g., desktop computers or laptops) or server computers, or mobile devices such as tablets or smartphones, to manage hardware and software resources and provide computing services, but the present invention is not limited to.

As shown in FIG. 1, a computer system 10 may include a storage device 101 and processing device 102 that are coupled to each other. The storage device 101 may be any kind of device that includes non-volatile memory (e.g., read only memory (ROM)), electrically-erasable programmable read-only memory (EEPROM), flash memory, non-volatile random access memory (NVRAM), such as a hard disk (HDD), a solid-state drive (SSD) or an optical disc, but the present invention is not limit to. The processing device 102 may include any kind of device for executing instructions, such as a central processing unit (CPU), a graphics processing unit (GPU), a microprocessor, a field-programmable logic gate array (FPGA), a neural processing unit (NPU), a controller, a microcontroller or a state machine, but the present invention is not limited to.

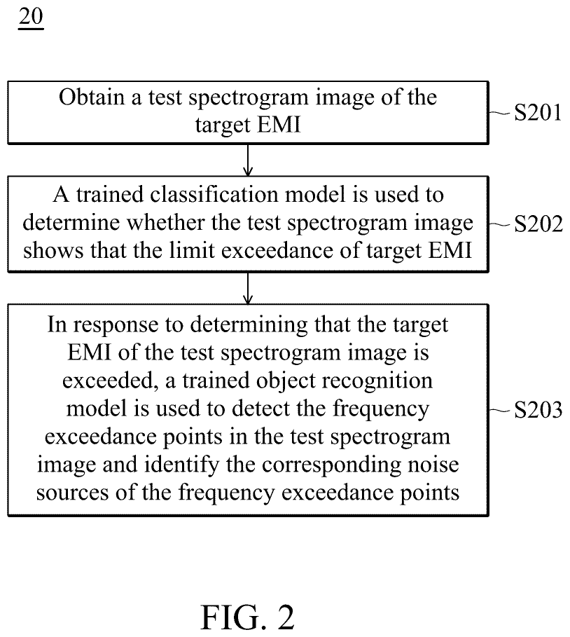

In an embodiment of the present invention, a storage device 101 is used to store a program. The program may be written in various known programming languages, such as C, C++, Python or Java, but the present invention is not limited to. The program includes a plurality of instructions, and when the processing device 102 loads the program from the storage device 101 and executes these instructions, an analysis method for electromagnetic interference exceedance can be implemented. This method is described in detail below with reference to FIG. 2.

FIG. 2 is a flow chart that depicts an analysis method 20 for analyzing electromagnetic interference exceedance according to one of the embodiments of the present invention. As shown in FIG. 2, method 20 may include steps S201 to S203.

In step S201, a test spectrogram image of the target EMI is obtained. The target EMI may depend on the field used and the standard of the equipment, and the goal is to identify and control the source of electromagnetic interference at a specific frequency, for example, it can be obtained in the context of electronic equipment design and testing, wireless communications, medical devices, etc., but the present invention is not limited to. The test spectrogram image may include a variety of information about the target EMI, such as frequency distribution, signal strength, characteristics of a specific frequency band, and whether there is any case of frequency point exceedance, but the present invention is not limit to.

In step S202, a trained classification model is used to determine whether the test spectrogram image shows that the limit exceedance of target EMI. The limit exceedance may mean that the EMI intensity emitted by the device in a certain frequency band exceeding the standard threshold of that frequency band. The threshold is subject to change depending on the application situation, and this disclosure does not limit the setting of the threshold. The trained classification model can be neural networks, decision trees, logistic regression, support vector machines (SVM), random forest, etc., but the present invention is not limited to.

In step S203, in response to determining that the target EMI of the test spectrogram image is exceeded, a trained object recognition model is used to detect the frequency exceedance points in the measured spectral image and identify the corresponding noise sources of the frequency exceedance points. The noise source can be the interference of electronic equipment and industrial equipment, such as, mobile phone, wireless router, Bluetooth equipment, electroplating equipment, transformer, etc. It can also be an electromagnetic phenomenon in nature, such as lightning strike, but the present invention is not limited to. The trained object recognition models can use regions with convolutional neural network (R-CNN) for feature extraction and classification, or the You Only Look Once (YOLO) model of end-to-end real-time detection, but the present invention is not limited to.

In one of the embodiments, the computer system 10 may further include a communication interface, and the communication interface allows the computer system to communicate with other devices to obtain the spectrogram image under test, wherein the communication interface may be a wired communication interface, such as a high-definition multimedia interface (HDMI), DisplayPort (DP) interface, embedded DisplayPort (eDP) interface, Universal Serial Bus (USB), USB Type-C interface, Thunderbolt interface, Digital Video Interface (DVI) and its combinations, it can also be a wireless communication interface, the 5th generation (5G) wireless system, Bluetooth, WiFi, Near Field Communication (NFC) interface . . . , etc., but the present invention is not limit to.

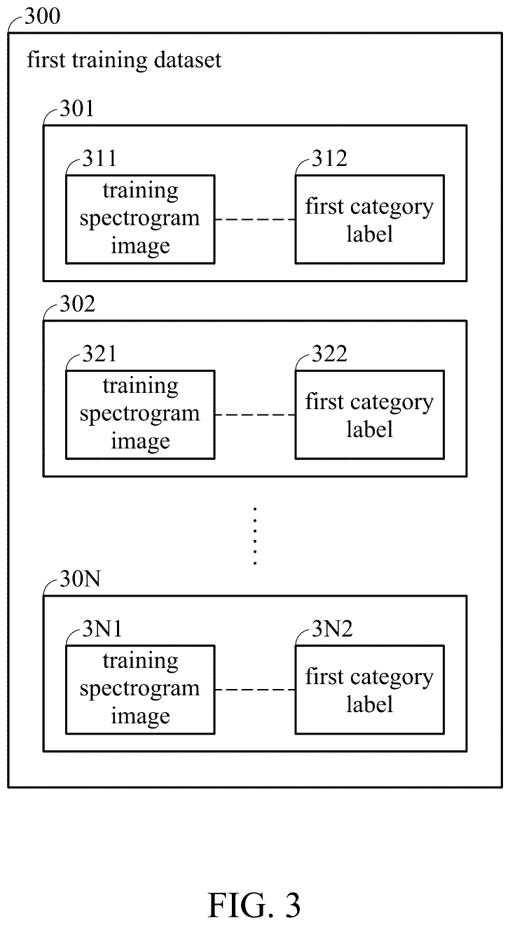

In one of the embodiments, the computer system 10 can train a classification model using the first training dataset. The first training dataset will be detailed below with reference to FIG. 3.

FIG. 3 is a schematic diagram of the structure of the first training dataset 300 according to one of the embodiments of the present invention. As shown in FIG. 3, the first training dataset 300 may include a plurality of the first training data, such as the first training data 301, 302 and 30N. Each training data includes a historical EMI training spectrogram image and its corresponding first category labels. For example, the first training data 301 includes a training spectrogram image 311 and its corresponding first category label 312, the first training data 302 includes a training spectrogram image 321 and its corresponding first category label 322, the first training data 30N includes a training spectrogram image 3N1 and its corresponding first category label 3N2, and so on.

Historical EMI refers to the basic EMI data required for model training, usually collected from past observations or events. The training spectrogram image may include a variety of characteristics of historical EMI, such as frequency distribution, signal strength, characteristics of specific frequency bands, etc., but the present invention is not limit to. The first category label is used to indicate whether the corresponding training spectrogram image shows historical EMI exceedance. For example, the first category label 312 indicates whether the training spectrogram image 311 shows historical EMI exceedance, the first category label 322 indicates whether the training spectrogram image 321 shows historical EMI exceedance, the first category label 3N2 indicates whether the training spectrogram image 3N1 shows historical EMI exceedance, and so on. These first category labels can be implemented with binary category labels, e.g. “1” for historical EMI exceedance, “0” for historical EMI not exceeded, or vice versa.

In the training process of the classification model, the training spectrogram image and its corresponding first category label can be used as the ground truth to evaluate the prediction or inference performance of the classification model. Further, loss functions such as cross-entropy, focal loss, hinge loss, and Kullback-Leibler divergence, etc., can be used to calculate the loss value that symbolizes the difference between the inference result of the classification model and the ground truth, and iteratively adjust the parameters of the classification model through the optimizer to minimize the loss value, so as to optimize the classification model.

The optimizer may adopt a gradient descent method (GD) and its variants, such as stochastic gradient descent (SGD) or adaptive moment estimation (Adam), but this disclosure is not limited to. The optimizer calculates the gradient of the loss value and adjusts the parameters of the classification model based on the gradient. Through repeated feedback of results and the training process of updating parameters, the loss value is gradually reduced to improve the accuracy of the classification model.

In one of the embodiments, the training spectrogram image can be derived from the EMI test report. Specifically, the EMI test report can be converted into a test report image, and then the training spectrogram image can be extracted from the test report image according to the boundary information of the training spectrogram image. The EMI test report can be a test file generated during the product development phase, which can be obtained by the test team in the product development side, or produced by a certified third-party electromagnetic compatibility (EMC) testing laboratory (e.g. a laboratory with anechoic chambers).

EMI test reports are usually obtained by radiated emission measurements in an anechoic chamber and recorded in a standardized file including information such as spectrograms, frequency and power data, test conditions and equipment parameters, but the present invention is not limited to. In order to facilitate the analysis of the machine learning models, the EMI test report (e.g., pdf file) can be converted into a test report image through a conversion program, and then the corresponding training spectrogram image can be extracted from the test report image according to the boundary information of the training spectrogram image.

The boundary information of the training spectrogram image can be determined by the position and range of the training spectrogram image in the EMI test report. In an embodiment, the boundary information can include the pixel coordinates of the upper left vertex and the lower right vertex of the training spectrogram image in the test report image. In another embodiment, the boundary information can include the pixel coordinates of the upper right vertex and the lower left vertex of the training spectrogram image in the test report image. In another embodiment, the boundary information can include a combination of the coordinates of the center point and any vertex coordinates of the training spectrogram image in the test report image. In another embodiment, the boundary information can include the coordinates of the center point or any vertex of the training spectrogram image in the test report image, as well as the dimensions of the test report image, such as width and height.

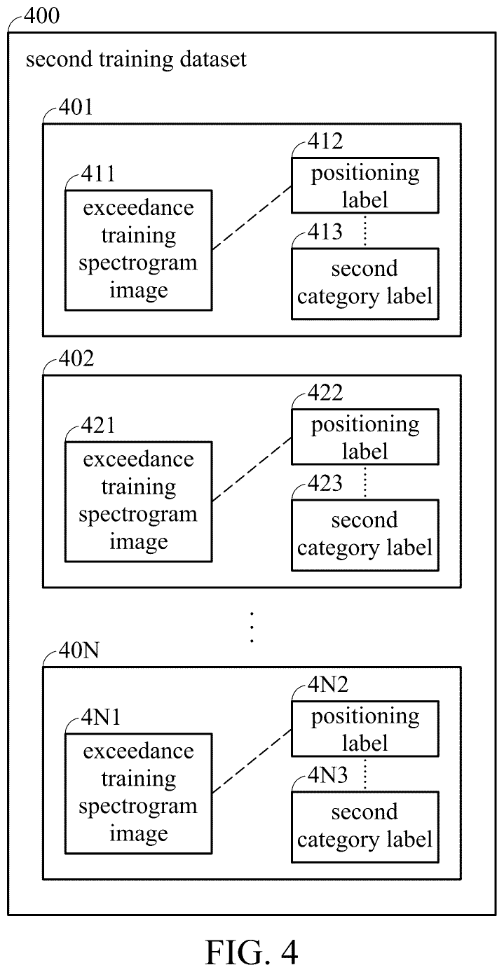

In an embodiment, the computer system 10 may use a second training dataset to train an object recognition model. The second training dataset will be detailed below with reference to FIG. 4.

FIG. 4 is a schematic diagram of the structure of the second training dataset 400 according to one of the embodiments of the present invention. As shown in FIG. 4, the second training dataset 400 may include a plurality of second training data, such as the second training data 401, 402 and 40N. Each second training data includes an exceeding training spectrogram image of historical EMI, positioning labels, and second category labels corresponding to the positioning labels. For example, the second training data 401 includes an exceedance training spectrogram image 411, a positioning label 412 and a second category label 413 corresponding to the positioning label 412, the second training data 402 includes an exceedance training spectrogram image 421, a positioning label 422 and a second category label 423 corresponding to the positioning label 422, the second training data 40N includes an exceedance training spectrogram image 4N1, a positioning label 4N2 and a second category label 4N3 corresponding to the positioning label 4N2, and so on.

The exceeding training spectrogram image can be selected from the training spectrogram image to select the EMI exceedance ones. The positioning labels may indicate the position of the exceeding spectrum in the exceedance training spectrogram images, such as the frequency exceedance points. The positioning label may be manually labelled or automatically annotated by a rule-based algorithm, but the present invention is not limited to. The second category label is used to indicate the noise source category of the exceeding frequency point, which may depend on the characteristics such as frequency, intensity data or color intensity (e.g., color in heat map) corresponding to the positioning label, but the present invention is not limit to. For example, the second category label 413 indicates the noise source category of the positioning label 412, the second category label 423 indicates the noise source category of the positioning label 422, the second category label 4N3 indicates the noise source category of the positioning label 4N2, and so on.

In the training process of the object recognition model, the exceeding training spectrogram images and their corresponding positioning labels and second category labels can be used as ground truth to evaluate the prediction or inference performance of the object recognition model. Furthermore, the loss functions such as cross-entropy, focus loss, smooth L1 loss, and generalized intersection over union (GIoU loss) can be used to calculate the difference between the category prediction and position prediction of the object identification model and the ground truth, respectively. During the training process, the optimizer can iteratively adjust the parameters of the object recognition model to minimize the loss value, thereby improving the classification accuracy and positioning accuracy of the model.

The optimizer may be implemented by the gradient descent method and its variants, such as the stochastic gradient descent method or the adaptive moment estimation method, but this disclosure is not limited to. The optimizer calculates the gradient of the loss value and adjusts the parameters of the object recognition model based on the gradient. Through the repeated result feedback and parameter update training process, the loss value can be gradually reduced, so as to optimize the overall performance of the object recognition model.

In one of the embodiments, the noise source category may be derived from the EMI test report. Specifically, the EMI test report can be converted into a test report image, and then the noise source category can be parsed from the test report image, but the present invention is not limit to. These noise source categories can be trackpads, HDMI, power supplies, radars, and other interference, but the present invention is not limit to. The method of parsing the noise source category from the test report image can be optical character recognition (OCR) technology, which recognizes the text area in the test report image to capture the annotation information corresponding to the exceeding frequency point. The annotation information may include the name of the device component, the function module, the interface type (e.g., HDMI, ADP, Touchpad, etc.), and/or other descriptive text that reflects the source of the noise.

Furthermore, it can also be combined with the image block positioning technology to locate the area corresponding to the table of test data in the test report image first, and then perform text recognition processing on the area to improve the resolution accuracy. In other embodiments, the corresponding rule-based analytical logic can also be designed for test reports of different formats, or structured field extraction can be carried out by using the trained model. However, the present invention does not limit the above-mentioned analytical technology or its specific implementation.

The present invention is capable of using artificial intelligence (AI) to assist in solving EMI problems and provide engineers with accurate solutions. This not only greatly improves design efficiency, but also shortens design time and improves the overall efficiency of the workflow. Through the application of AI to keep pace with the times, the present invention will eventually be able to achieve a full range of EMI problem solving, and can quickly provide a reference for the source analysis of the EMI exceeding noise energy to products, whether there is an experienced engineer or not, the source of the noise can be identified in a short time and the specific frequency point can be determined, so as to greatly shorten the time of EMI analysis and debugging.

While various embodiments of the present invention have been described above, it should be understood that these are provided as examples only and are not limiting. Although the present invention has been depicted and described with respect to one or more embodiments, equivalent or known alterations and modifications will occur to others skilled in the art upon reading and understanding this specification and the annexed drawings. Furthermore, while particular features of the invention may have been disclosed only in one of several embodiments, such features may be combined with one or more other features of the other embodiments as may be desired and advantageous for any given or particular application. Therefore, the breadth and scope of the present invention should not be limited by any of the above-described embodiments. Rather, the scope of the invention should be defined according to the following claims and their equivalents.

Unless otherwise defined, all terms (including technical and scientific terms) used herein shall have the meaning commonly understood by one of ordinary skill in the art. Furthermore, terms defined in commonly used dictionaries should be interpreted according to their meaning in the relevant technical field and should not be understood in an idealized or overly formal sense, unless expressly defined otherwise herein.

The above paragraphs are described in a variety of aspects. Obviously, the teachings of this article can be implemented in a variety of ways, and any particular architecture or function revealed in the examples is only a representative case. According to the teachings of this article, it should be understood that the various states disclosed in this article may be implemented independently or in combination.

What is claimed is:

1. A method for analyzing electromagnetic interference (EMI) exceedance implemented by a computer system, comprising:
obtaining a test spectrogram image of a target EMI;
using a trained classification model to determine whether the test spectrogram image indicates a limit exceedance of the target EMI; and
in response to a determination that the test spectrogram image indicates the limit exceedance of the target EMI, using a trained object recognition model to detect one or more frequency exceedance points in the test spectrogram image and identifying a noise source corresponding to each of the frequency exceedance points.

2. The method as claimed in claim 1, further comprising:
using a first training dataset to train the trained classification model, wherein the first training dataset comprises a plurality of first training data, each of the plurality of first training data comprises a training spectrogram image of a historical EMI and a first category label associated with the training spectrogram image, and the first category label indicates whether the training spectrogram image shows an exceedance of the historical EMI.

3. The method as claimed in claim 2, further comprising:
converting an EMI test report into a test report image; and
extracting the training spectrogram image from the test report image according to boundary information associated with the training spectrogram image.

4. The method as claimed in claim 1, further comprising:
using a second training dataset to train the trained object recognition model, wherein the second training dataset comprises a plurality of second training data, each of the plurality of second training data comprising:
an exceedance training spectrogram image of a historical EMI;
one or more positioning labels associated with the exceedance training spectrogram image, wherein each of the positioning labels corresponds to a frequency exceedance point of the historical EMI; and
a second category label associated with each of the one or more positioning labels, the second category label indicating a noise source category of the frequency exceedance point.

5. The method as claimed in claim 4, further comprising:
converting an EMI test report into a test report image; and
parsing the noise source category from the test report image.

6. A computer system for analyzing electromagnetic interference (EMI) exceedances, comprising:
a storage device, configured to store a program; and
a processing device, configured to load the program to perform the following steps:
obtaining a test spectrogram image of a target EMI;
using a trained classification model to determine whether the test spectrogram image indicates a limit exceedance of the target EMI; and
in response to the determination that the test spectrogram image indicates the limit exceedance of the target EMI, using a trained object recognition model to detect one or more frequency exceedance points in the test spectrogram image and identifying a noise source corresponding to each of the frequency exceedance points.

7. The computer system as claimed in claim 6, wherein the processing device further uses a first training dataset to train the trained classification model, wherein the first training dataset comprises a plurality of first training data, each of the plurality of first training data comprising a training spectrogram image of a historical EMI and a first category label associated with the training spectrogram image, the first category label indicating whether the training spectrogram image shows an exceedance of the historical EMI.

8. The computer system as claimed in claim 7, wherein the processing device further performs:
a conversion of an EMI test report into a test report image, and extracting the training spectrogram image from the test report image according to boundary information associated with the training spectrogram image.

9. The computer system as claimed in claim 6, wherein the processing device further uses a second training dataset to train the trained object recognition model, wherein the second training dataset comprises a plurality of second training data, each of the plurality of second training data comprising:
an exceedance training spectrogram image of a historical EMI;
one or more positioning labels associated with the exceedance training spectrogram image, wherein each of the positioning labels corresponds to a frequency exceedance point of the historical EMI; and
a second category label associated with each of the one or more positioning labels, the second category label indicating a noise source category of the frequency exceedance point.

10. The computer system as claimed in claim 9, wherein the processing device further performs:
converting an EMI test report into a test report image and parsing the noise source category from the test report image.
